(19) United States
(12) Patent Application Publication
(10) Pub. No.: US 2023/0071827 A1
(43) Pub. Date: Mar. 9, 2023

(54) SEMICONDUCTOR MODULE

(71) Applicant: FUJI ELECTRIC CO., LTD., Kawasaki-shi (JP)

(72) Inventor: Kousuke KOMATSU, Matsumoto-city (JP)

(73) Assignee: FUJI ELECTRIC CO., LTD., Kawasaki-shi (JP)

(21) Appl. No.: 17/875,794

(22) Filed: Jul. 28, 2022

(30) Foreign Application Priority Data
Sep. 9, 2021 (JP) 2021-146738

(51) Int. Cl. H01L 23/00; H01L 23/057

(52) U.S. Cl. CPC H01L 24/40; H01L 24/32; H01L 24/48; H01L 24/73; H01L 23/057; H01L 2224/32225; H01L 2224/40997; H01L 2224/48175; H01L 2224/73221; H01L 2224/73263; H01L 2224/73265; H01L 2924/351

(57) ABSTRACT

A semiconductor module includes: an insulation layer; a semiconductor element that includes a main electrode and is mounted on the insulation layer; a wiring member that is electrically connected to the main electrode of the semiconductor element; a first resin that encases the semiconductor element and the wiring member; and a second resin that covers a part of the wiring member. A thermal decomposition temperature or a melting point of the second resin is greater than a maximum of guaranteed operating temperature of the semiconductor element and is less than a thermal decomposition temperature or a melting point of the first resin.

### CROSS REFERENCE TO RELATED APPLICATION

This Application claims priority from Japanese Patent Application No. 2021-146738, filed Sep. 9, 2021, the entire content of which is incorporated herein by reference.

### BACKGROUND OF THE INVENTION

### Field of the Invention

The present disclosure relates to semiconductor modules.

### Description of Related Art

A semiconductor module includes a semiconductor element mounted on an insulation substrate, a lead frame connected to a main electrode of the semiconductor element, and a housing storing the semiconductor element (for example, see Japanese Patent Applications, Laid-Open Publication Nos. 2015-41676, 2019-161967, and 2019-47549). The semiconductor element is joined to the insulation substrate and terminals. In such a semiconductor module, the semiconductor element, the lead frame, and other parts in the housing are encased in a resin material. Examples of the resin material used for encasing semiconductor elements include relatively soft materials such as gels, and relatively hard ones such as epoxy resins.

In general, a semiconductor element and a lead frame are encased in hard resin. If a continuous current flows through the semiconductor element for some reason, the semiconductor device will become hot due to heat generated therein. As a result, overheating by the semiconductor element deforms the resin (e.g., expansion of the volume of the resin due to thermal decomposition of the resin), and the insulation substrate, on which the semiconductor element is disposed, may be damaged (e.g., be cracked or deformed) due to pressure generated by the deformation of the resin.

### SUMMARY OF THE INVENTION

The present disclosure has as an object to prevent damage to the insulation substrate due to overheating of the semiconductor element, while maintaining the encasing performance of the semiconductor module.

A semiconductor module according to this disclosure includes: an insulation layer; a semiconductor element that includes a main electrode and is mounted on the insulation layer; a wiring member that is electrically connected to the main electrode of the semiconductor element; a first resin that encases the semiconductor element and the wiring member; and a second resin that covers a part of the wiring member, in which: a thermal decomposition temperature or a melting point of the second resin is greater than a maximum guaranteed operating temperature of the semiconductor element, and is less than a thermal decomposition temperature or a melting point of the first resin.

### BRIEF DESCRIPTION OF THE DRAWINGS

FIG. 1 is a plan view of part of a semiconductor module according to an embodiment.

FIG. 2 is a cross-sectional view taken along line II-II shown in FIG. 1, illustrating part of the semiconductor module.

FIG. 3 is a cross-sectional view taken along line III-III in FIG. 2, illustrating a lead frame and a sealed portion.

FIG. 4 is a cross-sectional view of a sealed portion of a semiconductor module according to a modification.

FIG. 5 is an enlarged cross-sectional view of the part at which a main electrode of a semiconductor chip and a lead frame are joined.

### DESCRIPTION OF THE EMBODIMENTS

Embodiments of the present disclosure will be described below with reference to the drawings. Dimensions and scales of parts differ, as appropriate, from actual dimensions and scales in the drawings. The embodiments described below are suitable specific examples of the present disclosure. For this reason, in the present embodiments, various limitations that are technically preferred are used. However, the scope of the present disclosure is not limited to these forms as long as there are no particular descriptions that limit the present disclosure in the description below.

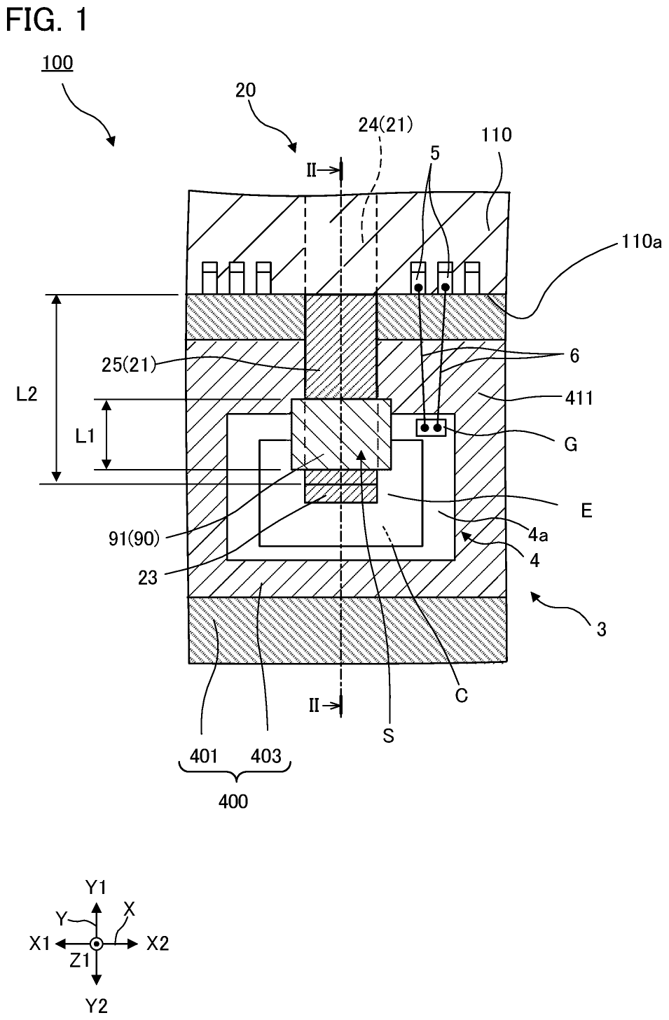

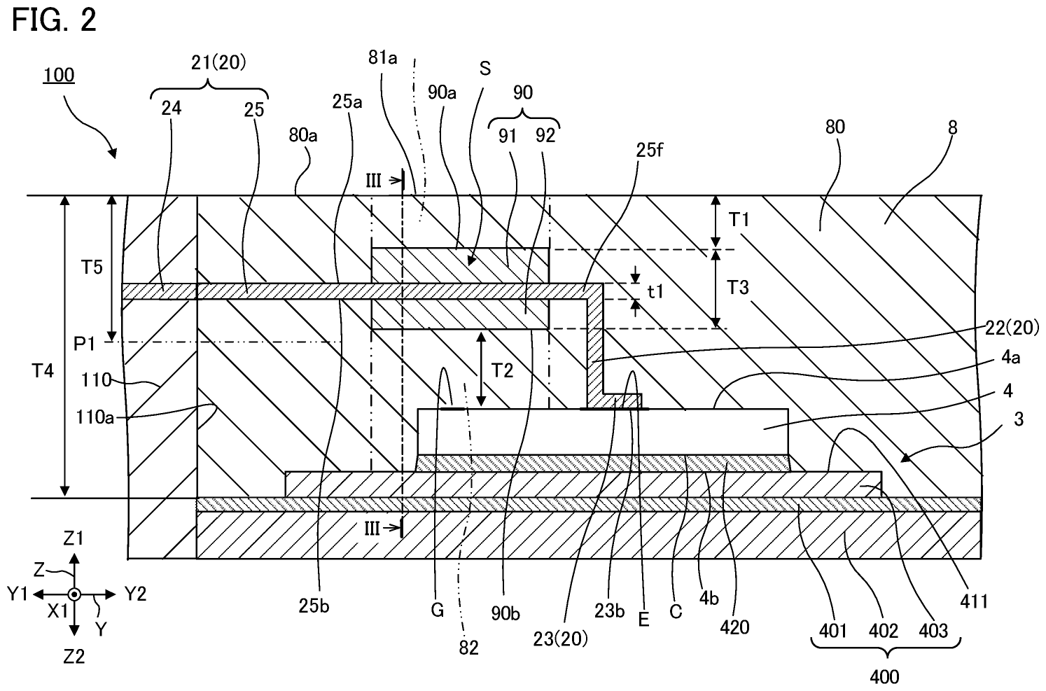

FIG. 1 is a plan view of part of a semiconductor module 100 according to the embodiment. FIG. 2 is a cross-sectional view taken along line II-II in FIG. 1, illustrating part of the semiconductor module 100. In each drawing, the X-axis, the Y-axis, and the Z-axis are orthogonal to each other. The Z2 direction is along the Z-axis and is an example of a first direction. The Z1 direction is opposite to the Z2 direction. The Y2 direction is along the Y-axis and is an example of a second direction. The second direction intersects the first direction. The Y1 direction is opposite to the Y2 direction. The X2 direction is along the X-axis and is an example of a third direction. The third direction intersects the first and second directions. The X1 direction is opposite to the X2 direction. The XY plane is parallel to the X-axis and the Y-axis. The XZ plane is parallel to the X-axis and the Z-axis. The YZ plane is parallel to the Y-axis and the Z-axis.

As illustrated in FIGS. 1 and 2, the semiconductor module 100 includes an enclosure 110, a lead frame 20, and a semiconductor unit 3. It is noted that the main part of the enclosure 110 is shown in FIGS. 1 and 2. The semiconductor module 100 is, for example, a power semiconductor module. Although FIGS. 1 and 2 show only one lead frame 20, the semiconductor module 100 may include a plurality of lead frames 20.

The enclosure 110 is formed of resin material having insulation properties. The resin material is, for example, thermoplastic resin. Examples of the resin material for the enclosure 110 include polybutylene terephthalate (PBT) and polyphenylene sulfide (PPS).

The enclosure 110 is formed so as to surround the semiconductor unit 3 when viewed in the Z2 direction. The enclosure 110 is, for example, a rectangular frame when viewed in the Z2 direction. The enclosure 110 has a specified thickness in the Z2 direction. The semiconductor unit 3 is disposed in the area surrounded by the enclosure 110.

The lead frame 20 is plate shaped and is formed of conductive metal material (e.g., copper). The lead frame 20 is not limited to copper, and it may be another metal material, for example, (i) a copper alloy containing 85% or more copper by weight, (ii) aluminum, and (iii) an aluminum alloy containing 85% or more aluminum by weight. The melting point of the lead frame 20 is, for example, 1,084 degrees Celsius. The melting point of the lead frame 20 may be 500 degrees Celsius or more and 1,100 degrees Celsius or less. The surface of the lead frame 20 may be coated with nickel or a nickel alloy. By the lead frame 20, an external terminal (not shown) and the semiconductor unit 3 are electrically connected each other. The lead frame 20 is an example of a wiring member.

The semiconductor unit 3 includes a multilayer substrate 400 and a semiconductor chip 4. The multilayer substrate 400 is a substrate on which the semiconductor chip 4 is mounted. The thickness direction of the multilayer substrate 400 is along the Z-axis direction. As illustrated in FIG. 2, the multilayer substrate 400 includes an insulation layer 401 and metal layers 402 and 403.

The insulation layer 401 is a resin insulation layer. For the resin composing the insulation layer 401, for example, epoxy resin may be employed. The resin composing the insulation layer 401 may contain various kinds of fillers, such as, silicon oxide, aluminum oxide, boron oxide, and boron nitride. The resin of the insulation layer 401 is not limited to epoxy resin, and it may be thermosetting resin, such as polyimide resin. The thermal decomposition temperature of the foregoing resin of the insulation layer 401 may be 200 degrees Celsius or more and 500 degrees Celsius or less. The “thermal decomposition temperature” means the temperature at which decomposition begins by heating, thereby beginning to the change state to gas, residues, or the like. The resin of the insulation layer 401 is an example of a fourth resin.

The thickness direction of the insulation layer 401 is along the Z2 direction. The insulation layer 401 is between the metal layers 402 and 403. The metal layers 402 and 403 include metals having high electrical conductivity and high thermal conductivity, and they may be metal plates o attached to the insulation layer 401. The metal layer 402 may be an aluminum plate or a copper plate. The metal layer 403 may be an aluminum plate or a copper plate or a copper foil.

The metal layer 402 is disposed on the lower side (the Z2 direction) of the insulation layer 401 and is grounded. The metal layer 403 is disposed on the upper side (the Z1 direction) of the insulation layer 401. The metal layer 403 has a conductor pattern 411. The conductor pattern 411 is a conductive film and is formed of conductive material having low resistance (e.g., copper or copper alloy).

The semiconductor chip 4 is a power semiconductor element that switches a large current ON or OFF . Examples of the semiconductor chip 4 include a transistor such as an insulated gate bipolar transistor (IGBT), a metal-oxide-semiconductor field-effect transistor (MOSFET), a reverse conducting IGBT (RC-IGBT) and a flyback diode (FWD). In this embodiment, an example will be given in which the semiconductor chip 4 is an RC-IGBT including an IGBT and a FWD.

As illustrated in FIG. 1, the semiconductor chip 4 includes a main electrode E, a main electrode C, and a control electrode G. Current for controlling the semiconductor chip 4 is input to, or output from, each of the main electrodes E and C. The main electrode E is an emitter electrode formed on the upper surface 4a of the semiconductor chip 4. The main electrode C is a collector electrode formed on the lower surface 4b of the semiconductor chip 4. The main electrode C acts as an anode electrode of the FWD, and the main electrode E acts as a cathode electrode of the FWD.

The control electrode G is formed on the upper surface 4a of the semiconductor chip 4 and is a gate electrode to which the voltage for controlling ON or OFF of the semiconductor chip 4 is applied. The control electrode G may include a detection electrode for current detection and for temperature detection.

As illustrated in FIG. 2, the semiconductor chip 4 is joined to the multilayer substrate 400, for example, by using a joining material 420 such as solder. The main electrode C of the semiconductor chip 4 is joined to the conductor pattern 411, which the main electrode C. The semiconductor module includes the semiconductor chip 4 mounted on the insulation layer 401. The “mounted on the insulation layer 401” means that it is directly mounted on the insulation layer 401. In addition, it means that it is indirectly mounted on the insulation layer 401 via other layers such as the metal layer 403.

As illustrated in FIG. 1, the semiconductor module 100 includes control terminals 5 that are provided in the enclosure 110. Each of the control terminals 5 is a lead terminal and is electrically connected to the control electrode G of the corresponding semiconductor chip 4 with a wire 6. Each control terminal 5 is formed integrally with the enclosure 110, for example, by insert molding.

Next, a description will be given of the lead frame 20. The lead frame 20 is formed of a metal plate by press working. The lead frame 20 includes a main part 21, a bent part 22, and a connecting part 23. The lead frame 20 has a crank structure including a main part 21, a bent part 22, and a connecting part 23. The crank structure is formed by bending a plate member.

The thickness direction of the main part 21 is along the Z2 direction. The main part 21 extends in the Y2 direction. The main part 21 includes a base part 24 embedded in the enclosure 110, a protruding part 25 continuous from the base part 24 and protruding from the enclosure 110 in the Y2 direction, and a fastening part (not shown) that is connected to an external terminal. The protruding part 25 extends in the Y2 direction. The fastening part is exposed to the outside of the enclosure 110. The fastening part may include a part embedded in the enclosure 110, or it may include a part protruding from the enclosure 110. The fastening part is connected to the opposite end of the base part 24 from the protruding part 25.

The base part 24 is embedded in the main part 21 of the enclosure 110. The base part 24 may include a bent part (not shown). The base part 24 is positioned between the fastening part and the protruding part 25. The protruding part 25 protrudes in the Y2 direction from an inner wall surface 110a of the enclosure 110. The protruding part 25 extends to a position that overlaps the semiconductor chip 4 when viewed in the Z2 direction. The thickness direction of the protruding part 25 is along the Z2 direction. The protruding part 25 includes a first surface (upper surface) 25a and a second surface (lower surface) 25b that opposes the first surface 25a, along the Z2 direction. The second surface 25b is closer to the insulation layer 401 than the first surface 25a. Here, the first direction is a direction that is directed from the semiconductor chip 4 toward the insulation layer 401.

The protruding part 25 is apart from the semiconductor chip 4 in the Z2 direction. The protruding part 25 is positioned above the semiconductor chip 4. The distal end 25f of the protruding part 25 is an end that is close to the semiconductor chip 4 and overlaps the semiconductor chip 4 when viewed in the Z2 direction.

The bent part 22 extends from the distal end 25f of the protruding part 25 along the Z2 direction and approaches the main electrode E of the semiconductor chip 4. The thickness direction of the bent part 22 is along the Y2 direction. The connecting part 23 protrudes from the bent part 22 in the Y2 direction. The thickness direction of the connecting part 23 is along the Z2 direction. The lower surface of the connecting part 23 includes a connecting surface 23b that is joined to the main electrode E of the semiconductor chip 4. The lead frame 20 is directly electrically connected to the main electrode E of the semiconductor chip 4. Alternatively, the lead frame 20 may be indirectly connected to the main electrode E of the semiconductor chip 4 via another member. The bent part 22 is an example of a first piece.

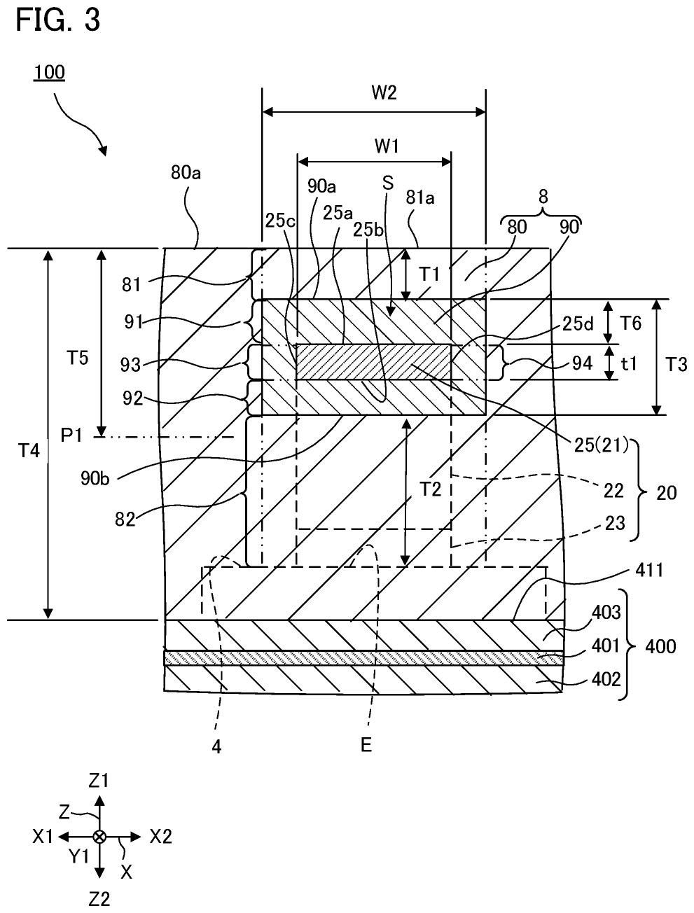

FIG. 3 is a cross-sectional view taken along line III-III shown in FIG. 2. As illustrated in FIGS. 2 and 3, the semiconductor module 100 includes a sealed portion 8. It is noted that the sealed portion 8 is not shown in FIG. 1. The sealed portion 8 includes a resin 80 and a resin block 90. The inner space surrounded by the enclosure 110 is filled with these resins, thereby encasing the semiconductor unit 3. The resin 80 is an example of a first resin, and the resin block 90 is an example of a second resin. The resin block 90 is rectangular, but it is not limited thereto.

Most of the sealed portion 8 is the resin 80. The resin 80 is disposed on the front surface of the multilayer substrate 400. By the resin 80, the multilayer substrate 400, the semiconductor chip 4, the lead frame 20 and the resin block 90 are encased. The resin 80 may be a thermosetting resin and is, for example, an epoxy resin. The resin 80 may contain various kinds of fillers made of, for example, silicon oxide, aluminum oxide, boron oxide, boron nitride, or the like. The resin 80 is not limited to epoxy resin, and it may be another thermosetting resin such as a phenol resin, maleimide resin, and polyester resin. The resin 80 may be a resin that is harder than the resin block 90.

The resin block 90 covers part of the lead frame 20. In particular, the resin block 90 covers part of the protruding part 25 of the main part 21. The surrounding of the resin block 90 is covered with the resin 80 and is not exposed to the outside. In other words, the resin block 90 is encased by the resin 80. As compared to a case in which the semiconductor chip 4 and the other parts are encased by only the resin block 90, degradation in mechanical strength of the semiconductor module 100 is reduced. Furthermore, degradation in the sealing property of the semiconductor module 100 is reduced. The reasons for this will be discussed below.

As illustrated in FIG. 3, the resin block 90 includes parts 91 to 94. The entire periphery of the cross section of the protruding part 25 is enclosed by the resin block 90. The part 91 is positioned on the upper side of the first surface 25a of the protruding part 25 of the lead frame 20. The part 91 is positioned to cover the first surface 25a of the protruding part 25. The part 91 covers the entirety of a part of the first surface 25a along the X2 direction. The X2 direction is an example of the width direction of the first surface 25a of the lead frame 20. The part 92 is located on the lower side of the second surface 25b of the protruding part 25 and covers the second surface 25b.

The protruding part 25 is between the parts 93 and 94. The protruding part 25 has a side surface 25c and a side surface 25d that opposes the side surface 25c, along the X2 direction. The part 93 covers the side surface 25c. The part 94 covers the side surface 25d. The side surface 25c is an example of a first side surface of the main part 21 of the lead frame 20, and the side surface 25d is an example of a second side surface of the main part 21.

As illustrated in FIG. 2, the resin block 90 has a specified length along the Y2 direction. The resin block 90 overlaps the semiconductor chip 4 and the metal layer 403 when viewed in the Z2 direction. The resin block 90 is closer to the bent part 22 and the connecting part 23 than to the inner wall surface 110a of the enclosure 110 in the Y2 direction. That is, the resin block 90 is close to the semiconductor chip 4 in the Y2 direction.

The resin block 90 is made of a thermosetting resin, specifically, a epoxy resin. The resin block 90 is not limited thereto, and it may be another thermosetting resin, such as a phenol resin, a maleimide resin, a polyester resin. Alternatively, the resin block 90 may be of a thermosetting elastomer such as a silicone rubber and a urethane rubber. Instead of thermosetting resin, the resin block 90 may be of a thermoplastic resin, specifically, a polyphenylene sulfide (PPS) resin. The resin block 90 is not limited to a PPS resin, and it may be another thermoplastic resin such as a polybutylene terephthalate (PBT) resin, a polybutylene succinate (PBS) resin and a polyamide (PA) resin. The resin block 90 may be thermoplastic elastomer such as a polystyrene-based (TPS), an olefin-based (TPO), a polyurethane-based (TPU), a polyester-based (TPEE) and a polyamide-based (TPAE). It is noted that the resin block 90 may contain various kinds of fillers made of silicon oxide, aluminum oxide, boron oxide, and boron nitride.

The following description is based on a case in which the resin block 90 is of a thermosetting resin. Description will be given later of a case in which the resin block 90 is of a thermoplastic resin. Thermal decomposition temperature of the thermosetting resin composing the resin block 90 is greater than the maximum guaranteed operating temperature of the semiconductor chip 4, and is less than the thermal decomposition temperature of the resin 80. In short, as long as the temperature generated in the semiconductor chip 4 is normal, the resin 80 and the resin block 90 remain unchanged. Furthermore, the thermal decomposition temperature of the resin block 90 is lower than that of the resin 80.

Preferably, the thermal decomposition temperature of the resin block 90 is greater than the guaranteed operating temperature of the semiconductor chip 4 by 10 degrees Celsius or more, and it is less than the thermal decomposition temperature of the resin 80 by 10 degrees Celsius or more. The guaranteed operating temperature of the semiconductor chip 4 is the temperature at which the semiconductor chip operates normally. The maximum guaranteed operating temperature of the semiconductor chip 4 is, for example, 175 degrees Celsius. The maximum guaranteed operating temperature may be 140 degrees Celsius or more and 180 degrees Celsius or less.

The thermal decomposition temperature of an epoxy resin composing the resin 80 is, for example, 320 degrees Celsius. The thermal decomposition temperature of the resin 80 may be 180 degrees Celsius or more and 500 degrees Celsius or less. The difference between the thermal decomposition temperature of the resin block 90 and the thermal decomposition temperature of the resin 80 may be 10 degrees Celsius or more and 300 degrees Celsius or less.

The crosslink density of the resin block 90 may be less than the crosslink density of the resin 80. The epoxy group concentration of the resin block 90 may be less than the epoxy group concentration of the resin 80. In other words, the epoxy equivalent of the resin block 90 may be greater than the epoxy equivalent of the resin 80.

The type of the epoxy resin composing the resin 80 may be different from that of the epoxy resin composing the resin block 90. For example, the resin 80 may be a novolac epoxy resin, and the resin block 90 may be a bisphenol A-type epoxy resin or a bisphenol F-type epoxy resin. In general, the heat resistant temperature of novolac epoxy resin is greater than that of bisphenol epoxy resin.

For example, the resin 80 may be a phenol novolac epoxy resin, and the resin block 90 may be a cresol novolac epoxy resin. For the novolac epoxy resin, in general, the heat resistant temperature of a phenol novolac epoxy resin is greater than that of a cresol novolac epoxy resin.

If the melting point of the resin of the enclosure 110 is too low, the resin may deteriorate due to heat from the base part 24 of the lead frame 20. If the melting point is too high, the temperature for molding the enclosure needs to be high, which makes the molding difficult.

In the light of the above, the thermal decomposition temperature of the thermosetting resin composing the resin block 90 is less than the melting point of the resin composing the enclosure 110. Preferably, the thermal decomposition temperature of the resin block 90 is less than the melting point of the resin composing the enclosure 110 by 10 degrees Celsius or more. The melting point of PBT resin included in the material of the enclosure 110 may be 225 degrees Celsius. The melting point of the resin may be 160 degrees Celsius or more and 300 degrees Celsius or less. The difference between the thermal decomposition temperature of the resin block 90 and the melting point of the resin composing the enclosure 110 may be 10 degrees Celsius or more and 100 degrees Celsius or less.

If the thermal decomposition temperature of the resin forming the insulation layer 401 is too low, the resin may deteriorate due to the heat from the semiconductor chip 4. If the thermal decomposition temperature is too high, the temperature for forming the substrate 400 needs to be high, and warping or the like tends to occur in the substrate 400 due to stress.

In light of the above, the thermal decomposition temperature of the resin block 90 is less than the thermal decomposition temperature of the resin forming the insulation layer 401. Preferably, the thermal decomposition temperature of the resin block 90 is less than the thermal decomposition temperature of the resin forming the insulation layer 401 by 10 degrees Celsius or more. The thermal decomposition temperature of the epoxy resin forming the insulation layer 401 is, for example, 320 degrees Celsius. The thermal decomposition temperature of the resin forming the insulation layer 401 may be 180 degrees Celsius or more and 500 degrees Celsius or less. The difference between the thermal decomposition temperature of the resin block 90 and the thermal decomposition temperature of the resin forming the insulation layer 401 may be 10 degrees Celsius or more and 300 degrees Celsius or less.

As illustrated in FIGS. 2 and 3, the resin 80 includes a part 81 and a part 82, along the Z2 direction. The resin block 90 is between the parts 81 and 82. The part 81 is an example of a first part of the first resin, and the part 82 is an example of a second part of the first resin. Each of the parts 81 and 82 of the resin 80 overlaps the resin block 90 when viewed in the Z2 direction. The part 81 of the resin 80 is positioned on the upper side of the part 91 of the resin block 90. The part 82 of the resin 80 is positioned on the lower side of the part 92 of the resin block 90.

If the thickness T1 is too small, the mechanical strength or the sealing property of the semiconductor module 100 may be reduced. If the thickness T1 is too great, and in addition, a continuous current flows through the semiconductor chip 4 for some reason, the insulation layer 401 may be damaged (cracked or deformed) due to overheating of the semiconductor chip 4. In such a case, the lead frame 20 and the metal layer 402 are electrically connected, which causes a grounding fault.

In light of the above, in the Z2 direction, the thickness T1 of the part 81 is less than the thickness T2 of the part 82. The thickness T1 of the part 81 is the distance from the upper surface 90a of the resin block 90 to the upper surface 81a of the part 81 of the resin 80. The thickness T1 of the part 81 may be the thickness at the thinnest part of the part 81. The thickness T2 of the part 82 is the distance from the upper surface 4a of the semiconductor chip 4 to the lower surface 90b of the resin block 90. The thickness T2 of the part 82 may be the thickness at the thinnest part of the part 82. Preferably, the thickness T1 is greater than or equal to 0.1 times the thickness T2 and less than or equal to 0.9 times the thickness T2.

In FIGS. 2 and 3, a first reference position P1 is shown. The first reference position P1 is a position that corresponds to 50% of the maximum thickness T4 of the resin 80 in the Z2 direction. The maximum thickness T4 is at the thickest part in the Z2 direction. The maximum thickness T4 may be the thickness from the upper surface of the multilayer substrate 400 to the upper surface 80a of the resin 80. The position of 50% of the maximum thickness T4 is a position that corresponds to 50% of the maximum thickness T4 from the upper surface 80a of the resin 80. The thickness T5 indicated in FIGS. 2 and 3 is at 50% of the maximum thickness T4. The resin block 90 is disposed on the opposite side of the first reference position P1 from the insulation layer 401. The resin block 90 is disposed on the upper side of the first reference position P1.

In the Z2 direction, the thickness T3 of the resin block 90 is greater than the thickness t1 of the protruding part 25 of the lead frame 20. The thickness t1 corresponds to the distance between the first surface 25a and the second surface 25b of the protruding part 25. The thickness t1 of the protruding part 25 of the lead frame 20 is 0.2 mm or more and 3.0 mm or less and is, for example, 1.0 mm. The thickness T3 of the resin block 90 corresponds to the distance from the lower surface 90b to the upper surface 90a of the resin block 90. The thickness T3 of the resin block 90 is, for example, 1.5 or more times and 10 or less times the thickness tl of the protruding part 25. The thickness T6 of the part 91 of the resin block 90 is, for example, 1.0 mm.

In the X2 direction, the width W2 of the resin block 90 is greater than the width W1 of the protruding part 25 of the lead frame 20. The width W2 of the resin block 90 may be less than the width W1 of the protruding part 25. The width W2 of the resin block 90 may be 110% or more, and 200% or less, of the width W1 of the protruding part 25.

As illustrated in FIG. 1, in the Y2 direction, the length L1 of the resin block 90 may be 5% or more, and 50% or less, of the length L2 of the protruding part 25 of the lead frame 20.

Next, a method for manufacturing the semiconductor module 100 will be briefly described. The lead frame 20 is placed in a metal mold, and the enclosure 110 is formed by mold forming in which resin is injected into a metal mold. Thereafter, the semiconductor unit 3 is placed in the enclosure 110, and the lead frame 20 is joined to the main electrode E of the semiconductor unit 3. Next, the resin block 90 is formed by insert molding, and the enclosure 110 is filled with the resin 80. This method for manufacturing the semiconductor module 100 is not limited thereto.

Next, the behavior of the semiconductor module 100 in an unusual situation will be described. In the semiconductor module 100, the semiconductor chip 4 receives a supply of current from an external electrode via the lead frame 20. In normal use, the resin 80, the resin block 90, and the resin of the enclosure 110 are at temperatures lower than the maximum guaranteed operating temperature of the semiconductor chip 4. Accordingly, these resins will not be thermally decomposed by heat from the lead frame 20.

When something unusual occurs during use, an excess current flows in the semiconductor chip 4. In such a case, the semiconductor chip 4 reaches high temperatures, and the heat therefrom is conducted to the lead frame 20. A part of the lead frame 20 closest to the semiconductor chip 4 (the connecting surface 23b, the distal end 25f and a part in contact with the resin block 90) melts.

The thermal decomposition temperature of the resin block 90 is lower than that of the resin 80. For this reason, the temperature of the resin block 90 exceeds the thermal decomposition temperature thereof prior to the resin 80. As a result, the thermal decomposition of the resin block 90 occurs, and the volume thereof decreases. Space S exists at the portion in which the resin block 90 was present, and it includes (i) air in minute gaps at the interface between the resin block 90 and the resin 80 and (ii) air in minute gaps at the interface between the resin block 90 and the lead frame 20.

Eventually, the air inside the space S is heated and expands. Because the part 81 (thickness T1) of the resin 80 is thinner than the part 82 (thickness T2) of the resin 80, cracks form in the less strong part of the resin 80 around the resin block 90. Specifically, the part 81 of the resin 80 on the part 91 of the resin block 90, not the part 82 of the resin 80 below the resin block 90, cracks. At this time, the protruding part 25 of the lead frame 20 has already melted, and the melted lead frame 20 leaks outward through the cracks of the part 81. The lead frame 20 is cut off, as a result of which the current supply from the external electrode to the semiconductor chip 4 stops, and the semiconductor chip 4 stops generating heat.

In the semiconductor module 100, when an unusual situation occurs, current supply to the semiconductor chip 4 stops, and this prevents or reduces heat generation of the semiconductor chip 4. Thus, damage to the insulation layer 401 due to overheating of the semiconductor chip 4 is prevented, and as a result, a grounding fault is prevented.

In the semiconductor module 100, since the thickness T1 of the part 81 is smaller than the thickness T2 of the part 82, the part 81 is easier to crack than the part 82. Furthermore, as shown in FIG. 2, the protruding part 25 of the lead frame 20 and the resin block 90 are disposed between the front surface (the upper surface 80a of the resin 80) and the first reference position P1 which is the intermediate position of the sealed portion 8. For this reason, the part 81 on the front surface will crack, as a result of which damage to the multilayer substrate 400 is mitigated.

In the semiconductor module 100, when an unusual situation occurs, the part 81 at a position away from the semiconductor chip 4 is damaged. However, damage to the resin 80 is minimal, and the sealing performance of the semiconductor module 100 is maintained. Furthermore, damage to the multilayer substrate 400 is prevented.

The semiconductor module 100 is not required to include a fuse outside the semiconductor module 100 because the lead frame 20 acts as a fuse when an unusual situation occurs.

Depending on the type of semiconductor module 100, in some cases, a lead frame different from the lead frame 20 is connected to the metal layer 403. The lead frame connected to the metal layer 403 need not include the resin block 90.

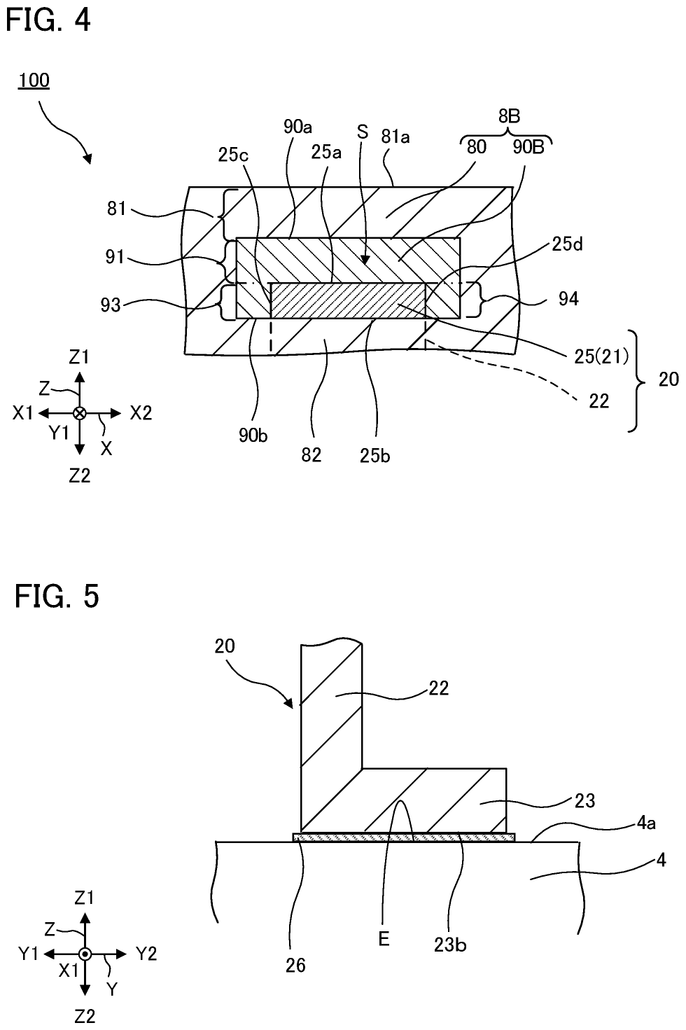

Next, a sealed portion 8B of a semiconductor module 100 according to a modification will be described. FIG. 4 is a cross-sectional view of the sealed portion 8B of the semiconductor module 100 according to the modification. The sealed portion 8B according to the modification does not include the part 92 that covers the second surface 25b of the protruding part 25 of the lead frame 20. This differs from the sealed portion 8 illustrated in FIGS. 2 and 3. The sealed portion 8B includes the resin 80 and a resin block 90B. The resin block 90B includes the part 91, the part 93, and the part 94. The semiconductor module 100 according to the modification does not include the part 92, and the second surface 25b of the protruding part 25 is covered by the resin 80.

The semiconductor module 100 including the sealed portion 8B provides an operational advantage the same as, or similar to, that of the semiconductor module 100 of the foregoing embodiment. When an unusual situation occurs, the resin block 90B thermally decomposes, and air inside the space S in which the resin block 90B was present, expands. As a result, cracks form on the part 81 of the resin 80, and the melted lead frame 20 leaks out through the cracks. The lead frame 20 is cut off, as a result of which the current supply to the semiconductor chip 4 stops. This prevents damage to the insulation layer 401, which results in preventing a grounding fault in the semiconductor module 100. In the semiconductor module 100 described above, when an unusual situation occurs, part 81 on the front surface cracks, and thus, damage to part 82 which is closer to the insulation layer 401 is prevented or reduced, and damage to the insulation layer 401 is avoided.

The resin block 90B shown in FIG. 4 may be formed in advance as a single component. The pre-formed resin block 90B can be attached to the protruding part 25 of the lead frame 20. In this case, a lead frame 20 with the resin block 90B attached to it by mold forming may be molded. Then, after the enclosure 110 is molded, the resin block 90B may be attached to the protruding part 25.

Alternatively, the resin block 90B may be formed on the protruding part 25 by other methods. In this case, the resin block 90B may be formed on the lead frame 20 by setting the lead frame 20 in a metal mold and injecting resin into the metal mold. The resin block 90 in the above embodiment can be formed in a manner the same as, or similar to, that for the resin block 90B. A resin block 90 formed in advance may be attached to the lead frame 20, or a resin block 90 may be formed on the lead frame 20 by using a metal molding. After the resin block 90 or 90B is provided to the lead frame 20, the resin 80 may be injected into the enclosure 110 to encase the semiconductor unit 3, the lead frame 20, and the resin block 90 or 90B in the enclosure 110.

Next, the part at which the main electrode E of the semiconductor chip 4 and the lead frame 20 are joined will be described with reference to FIG. 5. FIG. 5 is an enlarged cross-sectional view of the part at which the main electrode E of the semiconductor chip 4 and the lead frame 20 are joined. As illustrated in FIG. 5, the connecting surface 23b of the lead frame 20 is joined to the main electrode E of the semiconductor chip 4 via a joining member 26. The joining member 26 may be a solder or a metal sintered material. The solder may be a tin-based (Sn-based) solder. The metal sintered material may be a metal sintered material of silver (Ag) nanoparticles. As described above, the lead frame 20 may be joined to the main electrode E of the semiconductor chip 4 via the joining member 26.

Next, a description will be given of a case in which the resin block 90 is a thermoplastic resin. In the description below, the same description as in the case in which the resin block 90 is a thermosetting resin, will be omitted. The resin block 90 may be a thermoplastic elastomer. A thermoplastic resin and a thermoplastic elastomer has both a melting point and a thermal decomposition temperature. In general, these resins liquefy at the melting point, and after that (as the temperature rises further), it starts to turn into gas at the thermal decomposition temperature. When the resin block 90 reaches the melting point, the volume changes significantly. In light of the above, the melting point of the resin block 90 is higher than the maximum of the guaranteed operating temperature of the semiconductor chip 4 and is lower than the thermal decomposition temperature or the melting point of the resin 80.

As described above, the resin block 90 included in the semiconductor module 100 is of a thermoplastic resin. Such a semiconductor module 100 also provides an operational advantage the same as, or similar to, that of the semiconductor module 100 of the above embodiment.

Specifically, in normal use, because the resin 80, the resin block 90, and the resin of the enclosure 110 are at temperatures lower than the maximum of the guaranteed operating temperature of the semiconductor chip 4, they do not melt, nor do they thermally decompose.

When the lead frame 20 becomes hot in an unusual situation, heat from the semiconductor chip 4 is conducted to the lead frame 20. A part of the lead frame 20 closer to the semiconductor chip 4 melts. When the temperature of the resin block 90 exceeds the melting point of the resin block 90, the resin block 90 melts, and a space S in which the resin block 90 was present expands.

The expansion of the space S causes the part 81 of the resin 80 to crack. At this time, the protruding part 25 of the lead frame 20 has already been melted, and the melted lead frame 20 leaks out through the cracks of the part 81.

When an unusual situation occurs in the semiconductor module 100, the lead frame 20 is cut off. This prevents or reduces heat generation in the semiconductor chip 4. Thus, damage to the insulation layer 401 due to overheating of the semiconductor chip 4 is prevented, and as a result, a grounding fault is prevented.

The aforementioned example is only for showing a representative configuration of the present disclosure, and hence, the present disclosure is not limited to the aforementioned example. Thus, various kinds of modifications and additions are possible within the scope not departing from the spirit of the present disclosure.

In the above embodiment, a description is given of a configuration in which the wiring member is the lead frame 20, but the wiring member is not limited to the lead frame 20. The wiring member may be a lead frame having another configuration or a conductor in the form of a line such as a wire. The semiconductor module 100 may have a configuration in which the wiring member is a wire, and the wire may be provided with the resin block 90.

Although the above embodiment shows an example in which the lead frame 20 is directly joined to the semiconductor chip 4, the lead frame 20 may be electrically connected to the semiconductor chip 4 via a connection terminal. This connection terminal is a conductive block having a specified length along the Z2 direction

Although the above embodiment shows an example in which the lead frame 20 has the bent part 22 which is bent from the protruding part 25, the lead frame 20 may be one that does not have the bent part 22. If the lead frame 20 has the bent part 22, it is easy to provide separation between the protruding part 25 of the lead frame 20 and the semiconductor chip 4. In this case, the possibility of the insulation layer 401 being damaged is lower if the protruding part 25 and the resin block 90 are positioned near the upper surface 81a.

In the above embodiment, an example has been given in which thermal decomposition or melting of the resin block 90 results in expanding air inside the space S in which the resin block 90 was present, as a result of which part 81 of the resin 80 is damaged. However, the present disclosure is not limited to this case. For example, increased volume around the lead frame 20 due to melting of the lead frame 20 may damage the part 81. Alternatively, pressure of a gas generated from the resin block 90 may damage the part 81.

Although in the above embodiment, one lead frame 20 is provided with one resin block 90, the resin block 90 is not limited thereto. One lead frame 20 may be provided with two or more resin blocks 90. For example, two or more resin blocks 90 may be arranged at different positions in the Y2 direction. Alternatively, the resin block 90 may have a plurality of plate-shaped blocks stacked in the Z2 direction.

It is not required to integrally form all of the parts 91 to 94 of the resin block 90. For example, the resin block 90 may include a block including the parts 91, 93, and 94 integrally formed and a plate-shaped block of the part 92.

In the above embodiment, an example has been described in which the resin block 90 covers the first surface 25a, second surface 25b, and side surfaces 25c and 25d of the lead frame 20. However, it is not limited to thereto. The resin block 90 may cover at least part of the first surface 25a of the lead frame 20. The resin block 90 may include the part 91 and may not include the parts 92 to 94.

In the above embodiment, an example has been described in which the part 91 of the resin block 90 covers a part of the first surface 25a of the lead frame 20 along the X2 direction. However, the part 91 is not limited thereto. The part 91 may be one that covers the first surface 25a at part of the positions in the X2 direction. The width of the part 91 in the X2 direction may be smaller than the width W1 of the first surface 25a.

The semiconductor module 100 may include a plurality of wiring members, specifically, a plurality of wires. In this case, the resin block 90 may cover all the wires. Alternatively, each of the wires may be provided with a resin block 90.

Although the above embodiment shows an example in which the upper surface 90a of the resin block 90 is flat, the upper surface 90a is not limited to one that is flat. The upper surface 90a may include, for example, a curved surface, an inclined surface, or an uneven surface. Similarly, the other surfaces of the resin block 90, such as the lower surface 90b, are also not limited to ones that are flat, and may include curved surfaces, inclined surfaces, or uneven surfaces. The thickness T3 of the resin block 90 does not have to be uniform in the X2 and Y2 directions. Similarly, the thickness T1 of the part 81 of the resin 80 does not have to be uniform in the X2 and Y2 directions.

Although the above embodiment shows an example of a configuration in which the upper surface 90a of the resin block 90 is encased by part 81 of the resin 80, the resin block 90 is not limited to this. The upper surface 90a of the resin block 90 may not be encased by the resin 80. That is, the upper surface 90a of the resin block 90 may be exposed. Alternatively, the front surface of the semiconductor module 100 may be exposed. This reason is as follows: If the resin block 90 is encased, there is the possibility that moisture or the like will enter the inside of the sealed portion 8 through the interface between the resin block 90 and the resin 80. For this reason, corrosion of the lead frame 20 is avoided, and the reliability of the semiconductor module 100 is improved.

Although the above embodiment shows an example of a configuration in which the semiconductor chip 4 includes an RC-IGBT, the configuration of the semiconductor chip 4 is not limited to the above example. For example, the semiconductor chip 4 may include an IGBT or a MOSFET. In this case, the main electrode C is the source electrode, and the main electrode E is the drain electrode. Alternatively, the main electrode C is the drain electrode, and the main electrode E is the source electrode. The number of semiconductor chips 4 included in the semiconductor unit 3 is not limited to one. For example, the semiconductor unit 3 may include two or more semiconductor chips 4.

Although the above embodiment shows an example of a configuration in which the semiconductor module 100 includes one semiconductor unit 3, the number of semiconductor units 3 is not limited to one. For example, the semiconductor module 100 may include two or more semiconductor units 3.

The above embodiment shows an example of a configuration in which the semiconductor module 100 includes the enclosure 110. The semiconductor module 100 is not limited thereto. The semiconductor module 100 may include another container instead of the enclosure 110.

### DESCRIPTION OF REFERENCE SIGNS

100 . . . semiconductor module, 4 . . . semiconductor chip, 20 . . . lead frame, 21 . . . main part, 22 . . . bent part, 25 . . . protruding part, 26 . . . joining member, 80 . . . resin, 81 . . . part, 82 . . . part, 90 and 90B . . . resin block, 110 . . . enclosure, 401 . . . insulation layer, P1 . . . first reference position, t1 . . . thickness, T1 . . . thickness, T2 . . . thickness, T3 . . . thickness, T4 . . . maximum thickness

What is claimed is:

1. A semiconductor module comprising:
an insulation layer;
a semiconductor element that includes a main electrode and is mounted on the insulation layer;
a wiring member that is electrically connected to the main electrode of the semiconductor element;
a first resin that encases the semiconductor element and the wiring member; and
a second resin that covers a part of the wiring member,
wherein a thermal decomposition temperature or a melting point of the second resin is greater than a maximum of guaranteed operating temperature of the semiconductor element and is less than a thermal decomposition temperature or a melting point of the first resin.

2. The semiconductor module according to claim 1, wherein:
a direction that is directed from the semiconductor element toward the insulation layer is a first direction,
the first resin includes a first part and a second part along the first direction,
the second resin is between the first part and the second part in the first direction, and
in the first direction, a thickness of the first part of the first resin is less than that of the second part of the first resin.

3. The semiconductor module according to claim 2, wherein:
when viewed from the first direction, the second resin overlaps the semiconductor element,
in the first direction, the thickness of the second part of the first resin corresponds to a distance between the semiconductor element and the second resin, and
in the first direction, the thickness of the first part of the first resin is less than the thickness of the second part of the first resin.

4. The semiconductor module according to claim 1, wherein:
a direction that is directed from the semiconductor element toward the insulation layer is a first direction,
a position that corresponds to 50% of a maximum thickness of the first resin in the first direction is a first reference position, and
the first reference position is further between the second resin and the insulation layer in the first direction.

5. The semiconductor module according to claim 1, wherein:
a direction that is directed from the semiconductor element toward the insulation layer is a first direction,
the wiring member is a lead frame that is plate-shaped,
the lead frame includes a main part that extends in a second direction intersecting the first direction, and
the second resin covers a part of the main part.

6. The semiconductor module according to claim 5, wherein:
the main part of the lead frame includes a first surface and a second surface opposing the first surface along the first direction,
the second surface is closer to the insulation layer than the first surface in the first direction, and
the second resin covers at least a part of the first surface.

7. The semiconductor module according to claim 6, wherein:
a direction that intersects the first direction and the second direction is a third direction,
the main part of the lead frame further includes a first side surface and a second side surface opposing the first side surface, along the third direction, and
the second resin is block-shaped and covers (i) an entirety of a part of the first surface along the third direction and (ii) the first side surface and the second side surface.

8. The semiconductor module according to claim 7, wherein the second resin further covers the second surface.

9. The semiconductor module according to claim 5, further comprising: an enclosure that includes a third resin having insulating property and holds the lead frame, wherein:
the main part of the lead frame protrudes from the enclosure and extends along the second direction,
the lead frame includes a first piece that extends from the main part along the first direction and electrically connected to the semiconductor element, and
the second resin is closer to the first piece than to the insulating enclosure in the second direction.

10. The semiconductor module according to claim 9, wherein the thermal decomposition temperature or the melting point of the second resin is less than a thermal decomposition temperature or a melting point of the third resin.

11. The semiconductor module according to claim 5, wherein in the first direction, a thickness of the second resin is greater than that of the main part of the lead frame.

12. The semiconductor module according to claim 1, wherein:
the first resin includes a thermosetting resin, and
the second resin includes a thermosetting or thermoplastic resin.

13. The semiconductor module according to claim 1, further comprising: an enclosure that includes a third resin having insulating property and holds the wiring member, wherein:
the second resin includes a thermosetting or thermoplastic resin, and
the third resin includes a thermoplastic resin.

14. The semiconductor module according to claim 1, wherein the wiring member is directly connected to the main electrode of the semiconductor element.

15. The semiconductor module according to claim 1, wherein the wiring member is connected to the main electrode of the semiconductor element via a joining member.

16. The semiconductor module according to claim 1, wherein:
the insulation layer includes a fourth resin, and
the thermal decomposition temperature or the melting point of the second resin is less than a thermal decomposition temperature or a melting point of the fourth resin.

17. The semiconductor module according to claim 16, wherein:
the fourth resin includes a thermosetting resin, and
the second resin includes a thermosetting thermoplastic resin.
